(19) United States
(12) Patent Application Publication
(10) Pub. No.: US 2023/0063648 A1
(43) Pub. Date: Mar. 2, 2023

(54) MODULAR ELECTRICAL-CABINET MOUNTING APPARATUS

(71) Applicant: NAL LIMITED, Worcester (GB)

(72) Inventors: Michael MCGEE, Worcester (GB); Feargal O'CONNELL, Worcester (GB); Steven BROOKER, Worcester (GB); Darren MCCONVILLE, Worcester (GB)

(21) Appl. No.: 17/800,204

(22) PCT Filed: Jan. 20, 2021
(86) PCT No.: PCT/GB2021/050124

§ 371 Date: Aug. 16, 2022

(30) Foreign Application Priority Data
Feb. 18, 2020 (GB) 2002206.7

(51) Int. Cl. H02B 1/30

(52) U.S. Cl. CPC H02B 1/303

(57) ABSTRACT

A modular electrical-cabinet mounting apparatus (110) is provided comprising a base wall assembly (122) defining a cabling void (124) and a multi-part support platform (126) which is mountable to the base wall assembly (122) to at least partly cover the cabling void (124). The support platform (126) comprises a plurality of individual platform members (132a, 132b, 140) which are interconnectable to form the support platform (126). At least two said platform members are formed as cabinet-support members (132a, 132b) having a cabling access aperture therethrough and the support platform (126) is configured to be selectively assembled so that the cabinet-support members (132a, 132b) are in a spaced-apart relationship along the length of the support platform (126).

The present invention relates to a modular electrical-cabinet mounting apparatus which can be quickly and easily assembled, preferably, but not necessarily exclusively, in the provision of railway electrical cabinets. The invention further relates to a modular electrical-cabinet system comprising such a modular electrical-cabinet mounting apparatus. A method of providing a plurality of sequential electrical cabinets in a spaced apart relationship at a site requiring electrical cabling access and a modular electrical-cabinet mounting platform are also provided.

For signalling electrical cabinets used in the rail industry, a precast concrete base is provided at or adjacent to a railway line, upon which individual electrical cabinets can be installed. Cables are connected via T-section troughing to each individual electrical cabinet via a main troughing run. To interconnect adjacent electrical cabinets, separate troughing must be provided which is placed between each cabinet, which significantly increases the complexity of either manufacture of the concrete base, or installation and adaptation thereof.

Once installed, the cabinet base is filled with a large number of clay balls, designed to absorb and eliminate condensation, thereby protecting the electrical components within the electrical cabinets.

Predominantly, the cabinet sites will have from 1 to 5 electrical cabinets installed on a given concrete base, with 2 or 3 cabinets being most common. These electrical cabinets will generally fall into one of three categories: a large location cabinet; a half-signal location cabinet; and a fixed telecom network cabinet. Each cabinet is designed to contain different electrical components.

There are many issues with this approach. Firstly, the concrete base unit is difficult to move and level once initial installation has completed, since the crane or similar lifting device will depart from the site following delivery.

Furthermore, the connection to the cabinets via the troughing is poor, and will generally require a foam filler to make good, whilst the separate troughing between individual cabinets has similar problems which result in more poor connections.

In addition, the clay balls must be removed from the cabinet base when cables are added, and there is a common problem that these are not replaced after installation of the cables. This can lead to unexpected failure of the electrical components.

According to a first aspect of the invention, there is provided a modular electrical-cabinet mounting apparatus comprising: a base wall assembly defining a cabling void; and a multi-part support platform which is mountable to the base wall assembly to at least partly cover the cabling void, the support platform comprising a plurality of individual platform members which are interconnectable to form the support platform; at least two said platform members being cabinet-support members each having a cabling access aperture therethrough, the support platform being configured to be selectively assembled so that the cabinet-support members are in a spaced-apart relationship along the length of the support platform.

The ability to build a modular support mounting apparatus from easy-to-assemble individual components completely changes the way in which electrical cabinets can be installed. A base unit can be made to size, thereby defining a suitable cabling void, whilst defined-dimension cabinet-support members can then enclose the cabling void in such a way as to accept the desired electrical cabinets. This arrangement also obviates the need to provide the complicated troughing system which is provided for equivalent concrete structures. By providing the singular, unitary cabling void, cabling ducts can be used to bring cables to one single chamber which are capable of servicing multiple cabinets simultaneously. Further ducts could be used as outlets, thereby establishing a clear cabling pathway, and eliminating potential tangles.

Preferably, each cabinet-support member may comprise a frame and a panel mounted on the frame, the cabling access aperture being formed through the panel.

A multi-part cabinet-support member allows for a generic base frame to be created, so that only the dimensions of the panel supporting the cabinet itself needs altering in order to accommodate a specific category or class of cabinet.

Optionally, the frame may have a width which matches or substantially matches a width of the base wall assembly.

It is preferred, for simplicity of construction, that the base wall assembly only be extendable along one axis. As such, the width of the mounting apparatus is maintained across its full length, and therefore the standardized platform members will always fit into the base wall assembly.

The panel may preferably comprise at least one cabinet locator.

A cabinet locator may improve the ability to position the electrical cabinet in situ without the need for a weld join or similar integral formation which might otherwise inhibit subsequent maintenance of the mounting apparatus.

The or each cabinet locator may be formed as a locator hole.

A specific locator hole may be a simple means of ensuring that standardized cabinets can be easily inserted into place on a specific cabinet-support member.

Additionally, or alternatively, each cabinet support member may comprise a cabinet plinth through which the cabling access aperture passes. The cabinet plinth may be sub-divided into a plurality of plinth sections, each plinth section having an openable access door thereto.

In order to improve the working height of the electrical cabinet, a cabinet plinth may be provided upon which the electrical cabinet can be seated. This plinth also provides access to the cabling void without needing to dismantle the multi-part support platform, improving the ease of use of the apparatus.

Optionally, a plurality of different cabinet-support members may be provided, each of the different cabinet-support members having a cabling access aperture of a different dimension.

The concept of the present invention is to permit a system for rapidly setting up an electrical cabinet installation at a particular site, and more often than not, this will require electrical cabinets of different sizes and function. The provision of different cabinet-support members greatly improves the utility of the system as a whole.

At least one platform member may preferably be provided as a cover panel. Optionally, the or each cover panel may be formed from glass-reinforced plastic material.

It is preferred that platform members having functions other than for cabinet support be provided, in order to assist with ease of assembly and correct spacing of the cabinets with respect to one another so that maintenance can be easily performed.

In one preferable embodiment, the cover panel may be dimensioned so as to have a width greater than, and preferably at least twice, a width of a cabinet door of an electrical cabinet suitable for engaging with the multi-part support platform.

The dimensioning of the cover panels can be a simple way of enforcing a strict separation between adjacent electrical cabinets. In the current state of the art, it is possible to install cabinets too close to one another so as to hamper maintenance post-installation. Here, this problem is completely circumvented.

Preferably, a plurality of cabinet-support members may be provided, a said cover panel being positioned between each consecutive pair of cabinet-support members to form the multi-part support platform.

The regular spacing of the electrical cabinets using the cover panels ensures not only sufficient space for access for maintenance, but also results in an appealing final appearance of the apparatus once installed.

The cover panel may be openable to permit user access to the cabling void.

Firstly, opening the cabling void allows access to the underlying cables, which is useful for maintenance purposes. However, in view of the cabling void providing a means of stepping down relative to the electrical cabinets, openable cover panels also provide an engineer with an easy way of working on the electrical cabinets at a height which requires no bending. This improves the working conditions for the engineer.

Preferably, the platform members may be interconnectable so as to form a continuous upper surface of the multi-part support platform.

It is preferable that a continuous upper surface be formed to enclose the cabling void for the mounting apparatus, as this will significantly improve resistance to water ingress.

Optionally, each of the platform members may include a seating element engagable with an inner perimeter of the base wall assembly.

A seating element provides a simple means of securely locating the multi-part support platform in position with respect to the base wall assembly, simplifying the installation process.

The seating element may comprise a location tab dependent from the platform member which is receivable in the cabling void to engage with the inner perimeter of the base wall assembly.

Location tabs will assist with alignment of the multi-part support platform with respect to the base wall assembly, and engagement with the inner perimeter thereof limits the prospect for relative lateral movement of the various components.

Preferably, the location tab may abuttably engage with the inner perimeter of the base wall assembly.

Abuttable engagement with the base wall assembly may assist with retaining the multi-part support platform in position, so that there is no risk of dislocation.

The base wall assembly may be formed from a plurality of discrete wall sections which are interconnectable to form different dimensional variants.

A modularly constructible base wall assembly can be built to size with ease. The provision of individual wall sections means that a desired size can be readily achieved, and the sections can be dimensioned so that a plurality of platform members in sequence must be able to fit and cover the cabling void.

Preferably, the base wall assembly may comprise one or more removable portions for forming lateral access openings to the cabling void.

It may be preferred that the base wall assembly have specific and dedicated regions in which cabling ducts can be engaged without the need for significant freehand cutting by the installers. This will assist with limiting water ingress into the cabling void.

The modular electrical-cabinet mounting apparatus may further comprise a cabling duct engagable with the base wall assembly for providing lateral access to the cabling void.

A simple cabling duct system provides easy access in and out of the cabling void, avoiding the need for extensive internal troughing as is the case in the state of the art.

Optionally, the cabling duct may be aligned or substantially aligned to a centre of the cover panel when the multi-part support platform is assembled.

Cabling duct alignment may assist with visual identification of the positions of the inlet and outlet feed cables, which might otherwise become tangled in the open cabling void. This can also be useful for ensuring that the cabling is readily accessible to maintenance engineers.

Preferably, the cabling access aperture may include a gland tray.

Including a gland tray further improves the water-tightness of the cabling void, limiting the likelihood of failure of the equipment.

The modular electrical-cabinet mounting apparatus may optionally be provided in the form of a kit of parts.

The present invention is a unique solution for the placement of, in particular, rail controller-unit bases, allowing for installation from scratch at trackside. It is a complete, lightweight system, since no concrete is required, which can be built to size in situ. The complete modular system allows the end user to select a desired configuration of electrical cabinet sizes or types, with the cabling void size, and by extension base wall assembly, being dictated by the number of cabinet-support members required. Modules are simply placed onto the base wall assembly, bolted together, and then bolted onto the base. This can, in theory, all be achieved by a single engineer.

According to a second aspect of the invention, there is provided a modular electrical-cabinet system comprising: a modular electrical-cabinet mounting apparatus in accordance with the first aspect of the invention, and an electrical cabinet associated with each of the cabinet-support members, the or each cabinet being dimensioned to engage with and cover the corresponding cabling access aperture.

The ability to supply a site with a single useful cabinet base which can accommodate a variety of different electrical cabinet configurations provides a much-needed improvement to the installation of, in particular, rail controller-unit cabinets.

A door of each electrical cabinet may open towards or away from a subsequent electrical cabinet.

The door orientation of the cabinets can be aligned to the positioning of the cover panels. Since the cover panels can be dimensioned based on the door size, a situation in which misplacement of the electrical cabinets so that doors cannot be only partially opened by collision with other cabinets.

Preferably, each electrical cabinet may be a rail controller-unit cabinet.

The present invention is particularly suited towards replacing the existing methods of installing rail controller-unit cabinets, which, require large amounts of manpower and time to install correctly.

According to a third aspect of the invention, there is provided a method of providing a plurality of sequential electrical cabinets in a spaced apart relationship at a site requiring electrical cabling access, the method comprising the steps of: a] constructing a base wall assembly defining a cabling void, the base wall assembly having a length; b] interconnecting a plurality of individual platform members together to form a multi-part support platform which as a length greater than or equal to the length of the base wall assembly, wherein at least two said platform members are cabinet-support members having a cabling access aperture therethrough, the support platform selectively assembled so that the cabinet-support members are in a spaced-apart relationship along the length of the support platform; c] mounting the support platform to the base wall assembly; and d] mounting electrical cabinets onto the cabinet-support members.

During step b], a platform member which is formed as a cover panel may be positioned between each pair of cabinet-support members.

The present invention is particularly suited for arranging a plurality of sequential electrical cabinets in a given site, without the need for significant alterations to the base on which they stand to provide inter-chamber cable access. Furthermore, the provision of the intermediate cover panels provides a spacing means for ensuring that the separation between adjacent electrical cabinets is sufficient for later engineers to work comfortably on the cabinets.

According to a fourth aspect of the invention, there is provided a modular electrical-cabinet mounting platform comprising: a multi-part support platform which is mountable to a base to at least partly cover a cabling void defined therein, the support platform comprising a plurality of individual platform members which are interconnectable to alter a length of the support platform; at least one said platform member being a cabinet-support member having a cabling access aperture therethrough.

According to a fifth aspect of the invention, there is provided a modular electrical-cabinet mounting apparatus comprising: a base wall assembly defining a cabling void; and a multi-part support platform which is mountable to the base wall assembly to at least partly cover the cabling void, the support platform comprising a plurality of individual platform members which are interconnectable to form the support platform; at least one said platform members being a cabinet-support member having a cabling access aperture therethrough.

The invention will now be more particularly described, by way of example only, with reference to the accompanying drawings, in which:

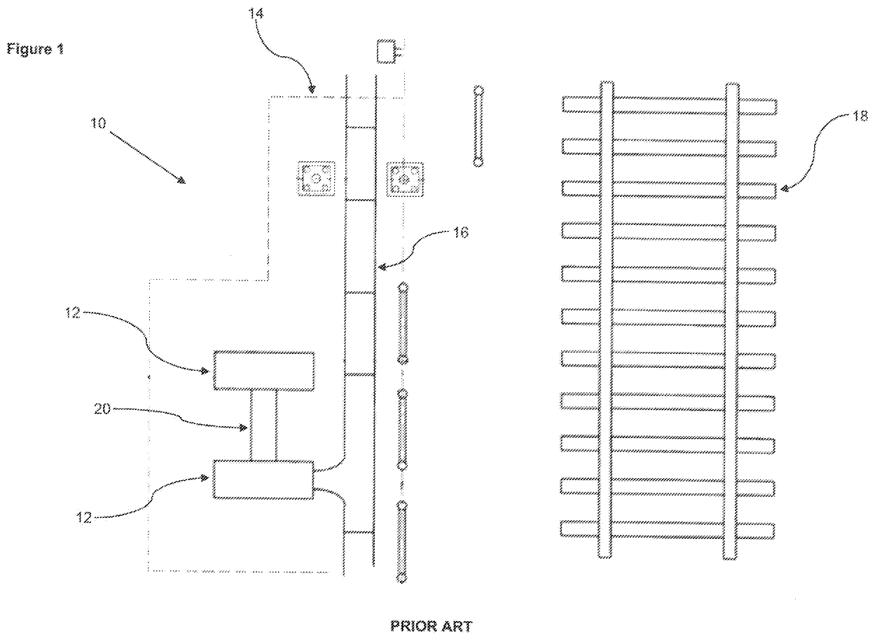

FIG. 1 shows a plan representation of an electrical cabinet system by a railway line, in accordance with the state of the art;

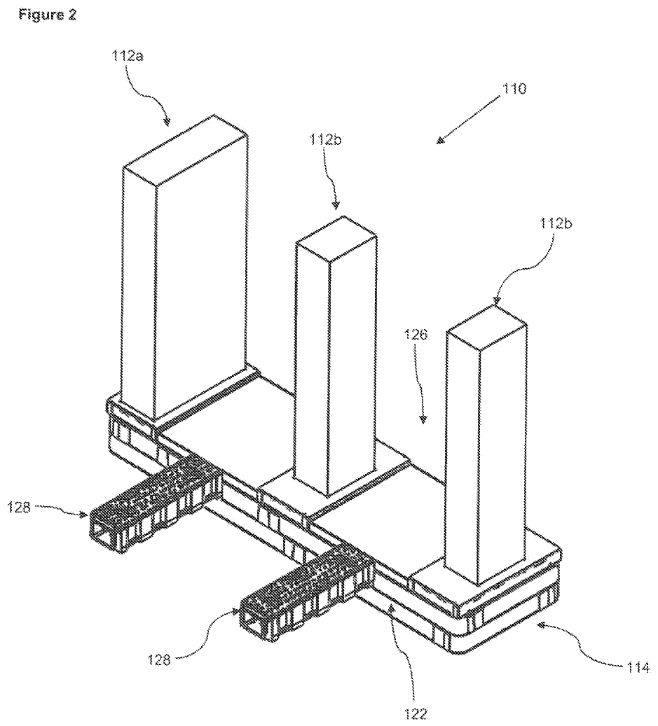

FIG. 2 shows a front isometric representation of one embodiment of a modular electrical-cabinet mounting apparatus in accordance with the first aspect of the invention, in, combination with three electrical cabinets to form a modular electrical-cabinet system in accordance with the second aspect of the invention;

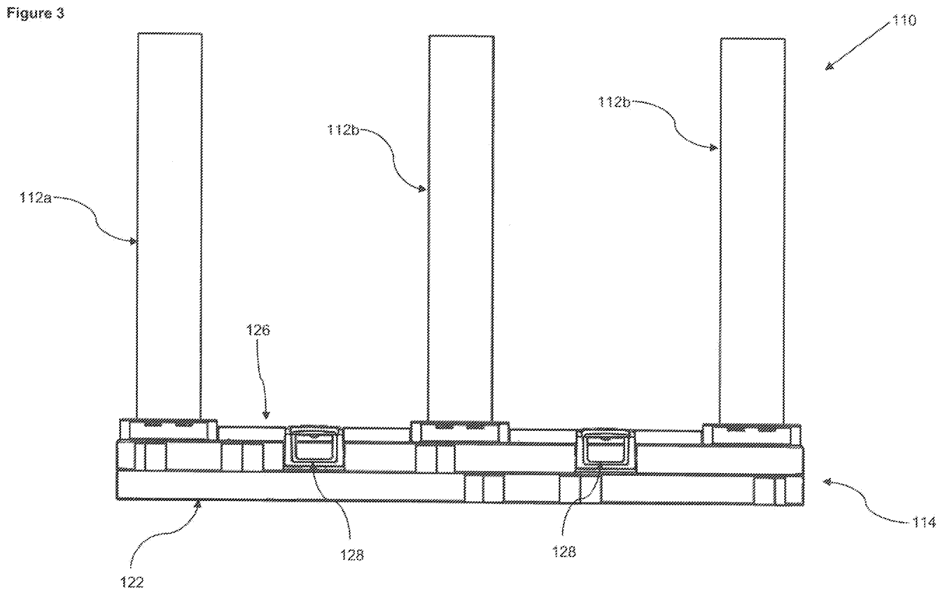

FIG. 3 shows a side view of the modular electrical-cabinet system shown in FIG. 2;

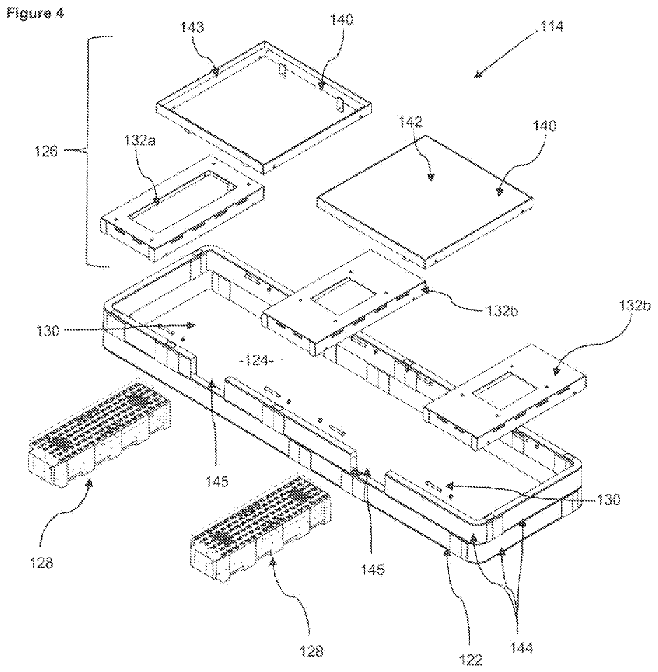

FIG. 4 shows an exploded representation of the modular electrical-cabinet mounting apparatus shown in FIG. 2;

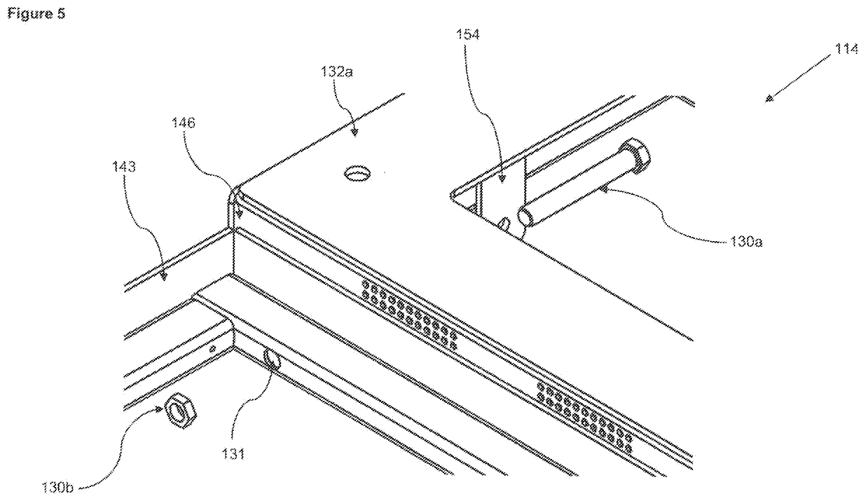

FIG. 5 shows an enlarged representation of the connection means of the modular electrical-cabinet mounting apparatus of FIG. 4;

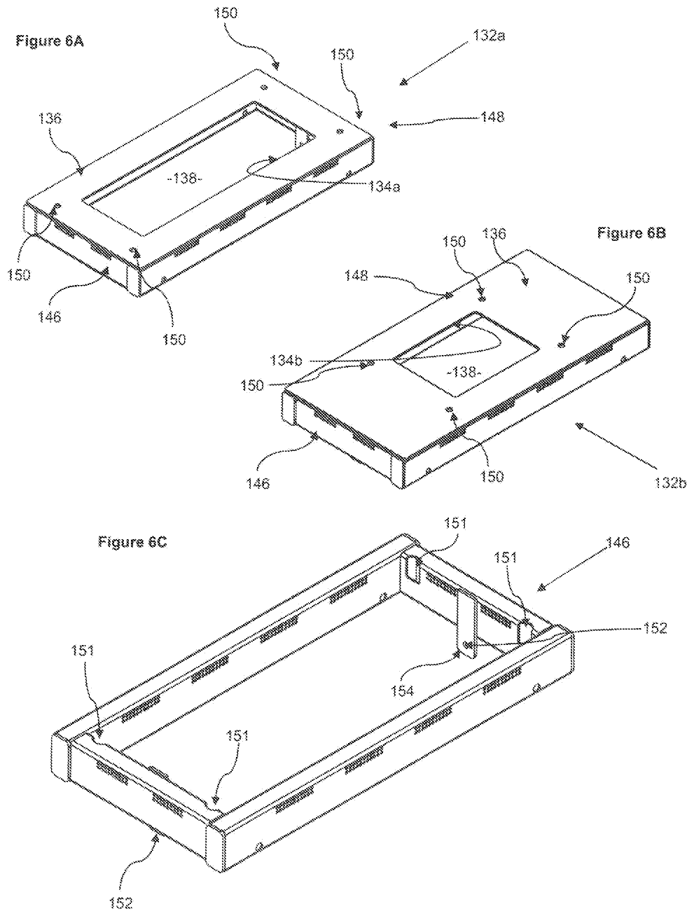

FIG. 6A shows an isometric representation of a first cabinet-support member of the modular electrical-cabinet mounting apparatus of FIG. 2;

FIG. 6B shows an isometric representation of a second cabinet-support member of the modular electrical-cabinet mounting apparatus of FIG. 2;

FIG. 6C shows an isometric representation of one of the frames for a cabinet-support member of the modular electrical-cabinet mounting apparatus of FIG. 2;

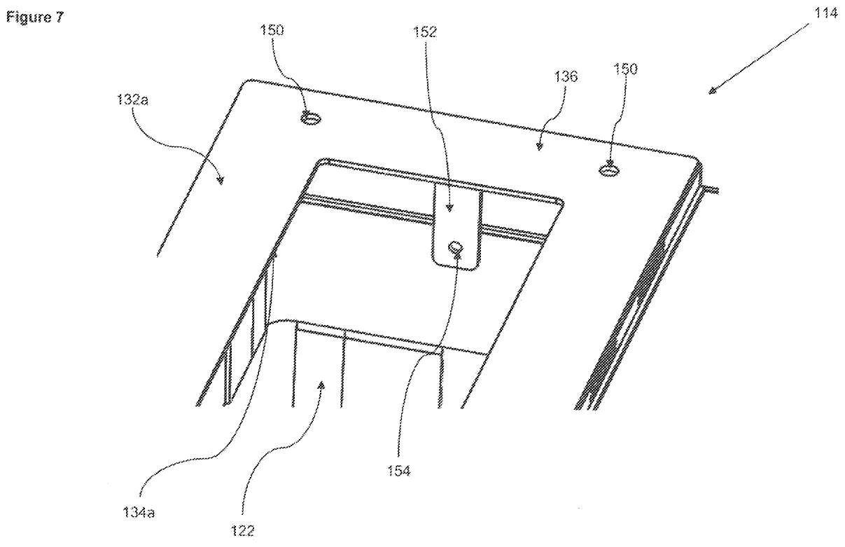

FIG. 7 shows an enlarged isometric representation of the interface between the first cabinet-support member and the base wall assembly of the modular electrical-cabinet mounting, apparatus of FIG. 2;

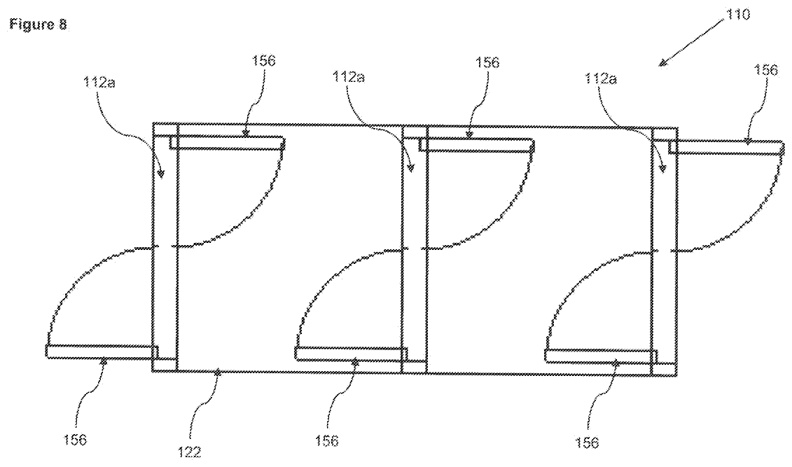

FIG. 8 shows a plan representation of a door-opening configuration of the modular electrical-cabinet system of FIG. 2;

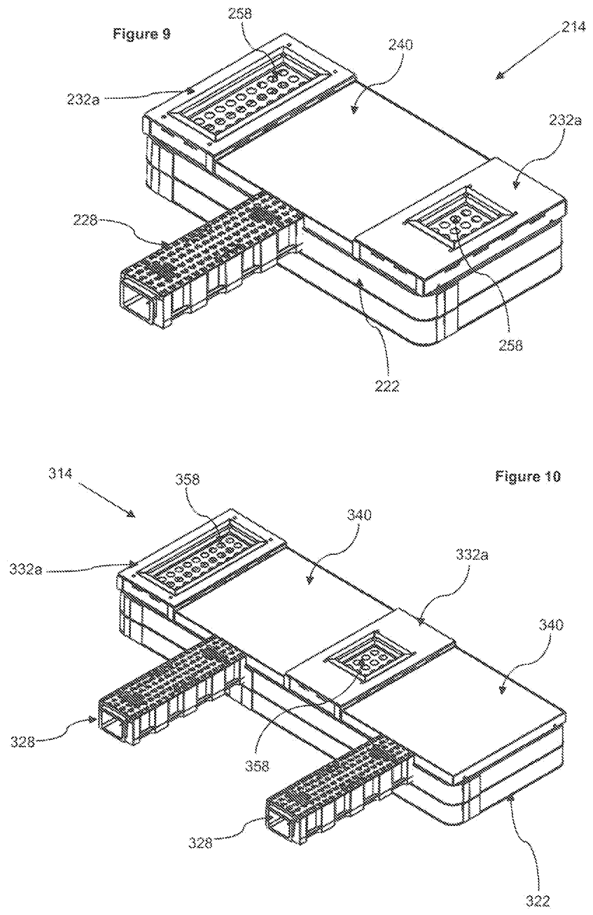

FIG. 9 shows a front isometric representation of a second embodiment of a modular electrical-cabinet mounting apparatus in accordance with the first aspect of the invention;

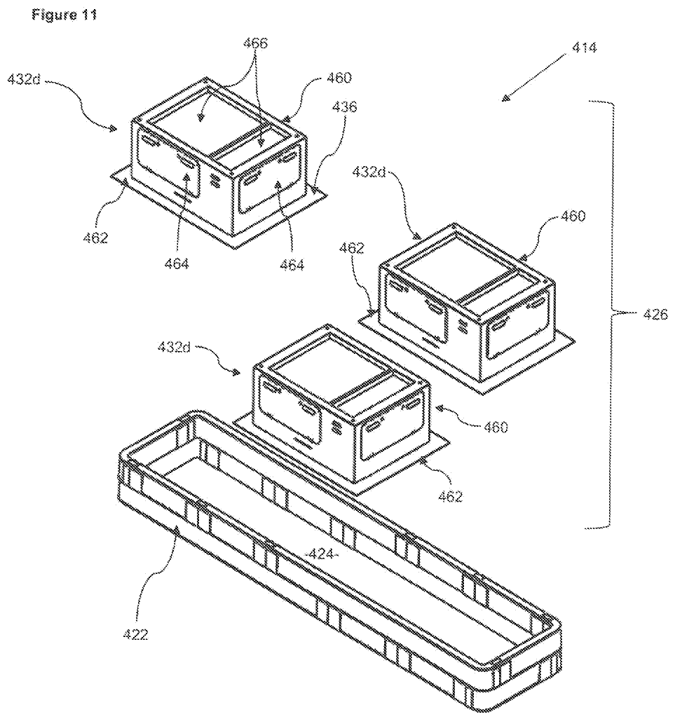

FIG. 10 shows a front isometric representation of a third embodiment of a modular electrical-cabinet mounting apparatus in accordance with the first aspect of the invention;

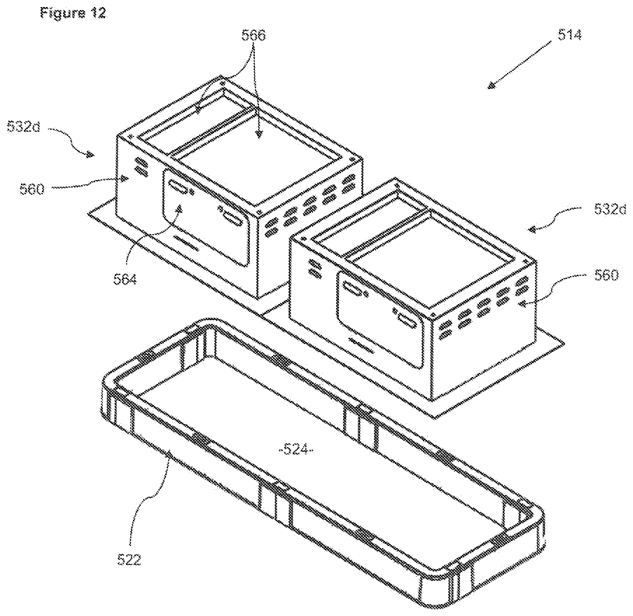

FIG. 11 shows a front isometric representation of a fourth embodiment of a modular electrical-cabinet mounting apparatus in accordance with the first aspect of the invention; and

FIG. 12 shows a front isometric representation of a fifth embodiment of a modular electrical-cabinet mounting apparatus in accordance with the first aspect of the invention.

Referring to FIG. 1, an illustrative electrical-cabinet system for a railway is indicated globally at 10, which is in accordance with the state of the art.

A plurality of electrical cabinets 12 is positioned on a solid concrete slab 14, with cabling being introduced to the electrical cabinets 14 through a main trough 16 which runs parallel to the railway track 18, and also via inter-cabinet troughs 20. The concrete slab 14 provides a good mounting position for the electrical cabinets 14, but is difficult to install in a level condition, as well as being challenging to correcting install the troughs 16, 20.

An alternative modular electrical-cabinet system 110 is indicated in FIGS. 2 and 3. The system 110 comprises a plurality of electrical cabinets 112a, 112b, which here comprise one full-width electrical cabinet 112a and two half-width electrical cabinets 112b. The electrical cabinets 112a, 112b are mounted onto a modular electrical-cabinet mounting apparatus 114.

The modular electrical-cabinet mounting apparatus 114 comprises a base wall assembly 122 which forms an enclosed or substantially enclosed perimeter for the modular electrical-cabinet mounting apparatus 114, defining a cabling void 124 therein, illustrated in FIG. 4, as well as a multi-part support platform 126 which is mountable to the base wall assembly 122 to at least partly cover the cabling void 124. The base wall assembly 122 may have one or more access openings in the perimeter which are engagable with one or more cabling ducts 128 to provide lateral access to the cabling void 124.

The multi-part support platform 126 can be seen in more detail in FIG. 4. The support platform 126 comprises a plurality of individual platform members which are interconnectable to form the support platform 126 in a desired configuration. Interconnection may be achieved via one or more fasteners, such as the fixing bolts 130 illustrated. Other connection means could be considered, however, such as interference fit, detent engagement, or indeed, the multi-part support platform 126 could be finalised by welding together, or otherwise integrally forming, the platform members with one another. Adjacent platform members may be connected by alignment of adjacent connection apertures 131 for instance, as can be seen more easily in FIG. 5 below.

The individual platform members may be provided in different forms. For example, there may be cabinet-support members 132a, 132b which include a cabinet locator 134a, 134b or receiver in an upper surface 136 thereof. The cabinet locator 134a, 134b is preferably dimensioned so as to be engagable with a specific class of electrical cabinet 112a, 112b. The cabinet locator 134a, 134b may include a locator hole, and thereby forms a cabling access aperture 138 through the upper surface 136 of each cabinet-support member 132a, 132b. The skilled reader will appreciate that the variety of electrical cabinets available precludes a complete recitation here.

Each cabinet-support member 132a, 132b may have a complete perimeter around its cabinet locator 134a, 134b which forms the upper surface 136, in order that a complete upper surface of the support platform 126 can be provided. This also minimises the risk of leak paths forming between an installed electrical cabinet 112a, 112b and its respective cabinet locator 134a, 134b, which might otherwise occur if a full perimeter surface was not present.

In addition to the cabinet-support members 132a, 132b, the multi-part support platform 126 may also include at least one further platform member, which may be provided as a cover panel 140. The cover panel 140 is preferably designed so as to be openable, for example, being hinged, or otherwise easily removable to permit user access to the cabling void 124. In particular, a user may be able to open the cover panel 140 to access and mounting apparatus within the cabling void 124, in order to operate on the electrical cabinets 112a, 112b at a more comfortable height.

The cover panels 140 may be arranged so as to sequentially interspace the cabinet-support members 132a, 132b, and therefore may also serve the function of providing a repeated spacing between adjacent cabinet-support members 132a, 132b. This may be carefully selected so as to be larger than a dimension of the access doors of the electrical cabinets 112a, 112b, preferably twice as large, and therefore preventing misplacement of the electrical cabinets 112a, 112b which can occur in the current state of the art.

The cover panels 140 have an upper surface 142 which when installed correctly, may provide a continuous, flush and/or contiguous surface for the support platform 126 with the upper surfaces 136 of the cabinet-support members 132a, 132b. Alternatively, and as can be seen in particular in FIG. 3, each cabinet-support member 132a, 132b may sit slightly proud of the upper surfaces 142 of the cover panels 140. The cover panel 140 itself may be connected to, and/or removably engagable with, a panel frame 143 which allows for the interconnection of the cover panel 140 as part of the multi-part support platform 126.

The base wall assembly 122 may itself be modular. As illustrated in FIG. 4, the base wall assembly 122 may comprise a plurality of individual wall sections 144 which can be interconnected in a selectable manner to build the base wall assembly 122 to a desired dimension, and in particular, to a desired length. It is preferred that a width of the base wall assembly 122 be maintained, as it is desirable for the width of the base wall assembly 122 be matched to that of the platform members of the support platform 126.

By increasing the number of wall sections 144 along the length of the base wall assembly 122, support platforms 126 of differing lengths can be accommodated. It may also be possible to provide for non-rectangular configurations, such as L- or T-shaped base wall assemblies 122, which may, increase the utility of the whole apparatus. Furthermore, the wall sections 144 may not only be connectable in an end-to-end relationship, but may be stacked on top of one another to increase the height of the base wall assembly 122 to suit the depth of foundation, required to accommodate the cabling void 124.

The cable ducts 128 can be seen in FIG. 4 in more detail, which are provided as elongate channels having a subsidiary cabling void therein. The bodies of the cable ducts 128 may be reinforced so as to provide sufficient structural support to an upper portion thereof, which may serve as a walking surface. The upper portion may therefore be positioned so as to be flush or substantially flush with the upper surface of the support platform 126, in use.

FIG. 4 shows the access openings 145 for connecting the cable ducts 128 to the cabling void 124. These access openings 145 could be pre-formed in the base wall assembly 122. However, it is preferred that one or more removable portions be provided in the base wall assembly 122, for example, frangible doors or covers, which could be selectively removed to allow for strategic positioning of the cabling ducts 128.

One strategically useful position of a cabling duct 128, which also results in an aesthetically pleasing symmetric appearance, is so as to be aligned with a centre of each cover panel 140. In this regard, the cables are always introduced into the cabling void 124 in a user accessible part of the modular electrical-cabinet mounting apparatus 110.

One example of a connection method of the multi-part support platform 126 can be seen in FIG. 5. The two-part fastener 130a, 130b can be inserted through adjacent connection apertures 131 of support platforms, here shown as a base frame 143 for a cover panel 140, and a frame 146 of the cabinet-support member 132a. The bolt 130a can be engaged with the nut 130b at different positions along the base frame 143 and frame 146 to ensure a secure connection, and this can be repeated along the length of the multi-part support platform 126.

FIGS. 6A and 6B show, respectively, the first and second different cabinet-support members 132a, 132b for supporting full-width and half-width electrical cabinets 112a, 112b. Each cabinet-support member 132a, 132b may be formed having a frame 146, such as that shown in FIG. 6C, to which is mounted a plate 148 which forms the upper surface 136 of the cabinet-support member 132a, 132b.

As previously noted, a cabling access aperture 138 is formed in the upper surface 136, which may be a panel, of each cabinet-support member 132a, 132b, and this forms the cabinet locator. However, the cabinet locator may comprise additional location elements, such as the secondary locators 150 shown. These secondary locators 150 may be dimensioned to receive pins attached to the electrical cabinets 112a, 112b in lieu of feet. Alternatively, said secondary locators may align to corresponding apertures on the electrical cabinets 112a, 112b, in order that additional fasteners, such as screw-threaded fasteners, may be used to connect the electrical cabinets 112a, 112b to their respective cabinet-support members 132a, 132b. Indeed, and as can be seen in FIG. 5C in particular, the frame 146 may include a plurality of fastener receivers 151 which are aligned to the secondary locators 150 to act as guides when the installer drills into the base wall assembly 122, allowing the base wall assembly 122 to be connected to the multi-part support platform 126. This may again be achieved via one or more fasteners 130.

The, preferably rectangular, frame 146 of each cabinet-support member 132a, 132b may be identical regardless of the size of electrical cabinet 112a, 112b to be supported. In this way, there is a consistent and repeatable dimension associated with each cabinet-support member 132a, 132b.

The frame 146 preferably provides the interface between the base wall assembly 122 and the multi-part support platform 126, and here this is achieved by the provision of seating elements, such as the projecting location tabs 152 which depend from the inner perimeter of the frame 146. The location tabs 152 prevent dislocation of the support platform 126 with respect to the base wall assembly 122 preferably by abutment with the inner perimeter along at least two walls for each frame 146. The location tabs 152 may also include engagement means for an additional connector, such as the aperture 154 for a fastener which is shown. Typically, fastening would only be required in the location tabs 152 in the four corners of the multi-part support platform 126.

This abuttable engagement can be seen best in FIG. 7. The location tabs 152 may even be formed so as to project slightly outwardly in order to create an additional interference fit with the base wall assembly 122. Other forms of seating element could be provided, however. For instance, a full perimeter skirt which sits inside or around the base wall assembly could also be considered.

If an engineer needs to work on a particular electrical cabinet 112a, 112b, then they can follow a simple process. A cover panel 140 adjacent to the desired electrical cabinet 112a, 112b can be selected and opened, with the engineer stepping in so that the electrical cabinet 112a, 112b is positioned at a comfortable relative working height. Additionally, the engineer has unfettered access to the cabling within the cabling void 124, rather than needing to engage with an inter-cabinet trough buried in concrete, as is the case in the state of the art.

The doors 156 of the electrical cabinets 112a, 112b can be configured to open towards or away from adjacent electrical cabinets 112a, 112b. A schematic representation of this door opening scheme is shown in FIG. 8. The schematic shown is not to scale—it is purely indicative of relative door positions, rather than the true length of electrical cabinets. It is preferred that each cover panel 140 be dimensioned to be at least as wide as the width of one said door 156, and more preferably, to be at least twice as wide as the width of a said door 156, so that doors can be opened on both sides of the cover panel 140.

Further embodiments of modular electrical-cabinet mounting apparatuses are shown in FIGS. 9 and 10 respectively. Identical or similar components to those described in relation to the first embodiment of the mounting apparatus above will be referred to using identical or similar reference numerals, and further detailed description will be omitted for brevity.

The modular electrical-cabinet mounting apparatus 214 of FIG. 9 has a cabinet-support member 232a dimensioned for a full-width electrical cabinet, and a cabinet-support member 232b dimensioned for a half-width electrical cabinet, which are separated by a single cover panel 240. This allows for a relatively short base wall assembly 222 to be constructed, having a single cable duct 228 access. Each cabinet-support member 232a, 232b incorporates a gland tray 258 for engaging with cables passed therethrough. This will assist with preventing water ingress into the cabling void.

The modular electrical-cabinet mounting apparatus 314 of FIG. 10 has a cabinet-support member 332a dimensioned for a full-width electrical cabinet, and a cabinet-support member 332b dimensioned for a half-width electrical cabinet, again, but now has an additional cover panel 340 which extends from one side of the second cabinet-support member 340. This allows for the base wall assembly 322 to be increased in size in order to accommodate a further cable duct 328. Again, each cabinet-support member 332a, 332b incorporates a gland tray 358 for engaging with cables passed therethrough.

Whilst the cabinet-support members of the preceding embodiments have all been formed as individual frameworks having a flat plate thereon which forms an upper surface of the multi-part support platform, this is not necessarily required.

A further embodiment of the modular electrical-cabinet mounting apparatus is shown in FIG. 11. Identical or similar components to those described in relation to the earlier embodiments of the mounting apparatus above will be referred to using identical or similar reference numerals, and further detailed description will be omitted for brevity.

Instead of flat plates, each cabinet-support member 432d of the modular electrical-cabinet mounting apparatus 414 is provided as a cabinet plinth 460 from which a perimetric flange 462 extends, the perimetric flange 462 forming the upper surface 436 of the multi-part support platform 426. The perimetric flange 462 may extend continuously around the cabinet plinth 460, or only part of the way around, with adjacent cabinet-support members 432d providing the necessary overlap to cover the cabling void 424.

In this embodiment, the base wall assembly 422 has been constructed so as to be able to receive three cabinet-support members 432d thereon, with each cabinet-support member 432d having a width equal to that of the base wall assembly 422.

An alternative embodiment of the modular electrical-cabinet mounting apparatus is shown in FIG. 12. Identical or similar components to those described in relation to the fourth embodiment of the mounting apparatus above will be referred to using identical or similar reference numerals, and further detailed description will be omitted for brevity.

In the further embodiment, the modular electrical-cabinet mounting apparatus 514 has a base, wall assembly 522 which has a smaller cabling void 524, dimensioned so that only two cabinet-support members 532d are required to cover the cabling void 524.

In either of the fourth or fifth embodiments, the cabinet-support members 432d; 532d are formed so as to have one or more raised access doors 464; 564 to permit an engineer to access the cabinet plinth 460; 560. This potentially obviates the need to provide a cover panel for the multi-part support platform, since the electrical cabinets will sit higher on top of the cabinet plinths 460; 560. An engineer can work on the electrical cabinet at a safe height, and will be able to access cables coming up through the cabling void 524, and through the cabling access apertures in the cabinet-support members 432d; 532d via the access doors 464; 564. Ventilation may also be provided to improve airflow into the cabling void without increasing the prospect of water ingress.

In the depicted embodiments, cover trays 466; 566 are illustrated which cover the tops of different sections of the cabinet plinths 460; 560. It will be appreciated that these can be removed and/or replaced with gland trays as required.

Where a plurality of different sections of the cabinet plinths 460; 560 are provided, each separate section may have a different access door 464; 564, so that there can be no tangling or mixing of the cables into or out of the different sections, and the engineer can work on each independently,

Hinged or pivotable access doors 460; 560 are shown, which fold down, but these access doors 460; 560 may hinge upwardly, laterally, or may indeed be completely removable to simplify user access thereto.

These additional embodiments of the invention highlight how the system can be readily adapted to cope with different dimensional variations which may be more or less appropriate for different contexts. As such, it is preferred that the components be provided as a kit of parts to allow for on-site assembly of the system to suit requirements.

The above-described modular electrical-cabinet systems have been thus far detailed in the context of rail controller-unit cabinet. However, it will be, appreciated that other contexts could be considered. For example, cabinets containing electrical equipment are utilised in the telecommunications, motorway communications, and power and energy distribution industries. The present invention is applicable in all of these contexts, and is not intended to be solely limited to use in the rail network.

It is therefore possible to provide a mounting apparatus for electrical cabinets which is modular. This allows the user to more readily build and install the electrical cabinets on site, in accordance with any location specific parameters which may make the installation of a concrete slab more problematic. Not only does the modular cabinet arrangement improve the ease of installation, it also simplifies the ease with which maintenance on the cabinets can be performed, since there is a much simpler means of access into the cabling void below the electrical cabinets.

The words ‘comprises/comprising’ and the words “having/including” when used herein with reference to the present invention are used to specify the presence of stated features, integers, steps or components, but do not preclude the presence or addition of one or more other features, integers, steps, components or groups thereof.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable sub-combination.

The embodiments described above are provided by way of examples only, and various other modifications will be apparent to persons skilled in the field without departing from the scope of the invention as defined herein.

1. A modular electrical-cabinet mounting apparatus comprising:
a base wall assembly defining a cabling void; and
a multi-part support platform which is mountable to the base wall assembly to at least partly cover the cabling void, the support platform comprising a plurality of individual platform members which are interconnectable to alter a length of the support platform;
at least two said platform members being cabinet-support members each having a cabling access aperture therethrough, the support platform being configured to be selectively assembled so that the cabinet-support members are in a spaced-apart relationship along the length of the support platform.

2. The modular electrical-cabinet mounting apparatus as claimed in claim 1, wherein each cabinet-support member comprises a frame and a panel mounted on the frame, the cabling access aperture being formed through the panel.

3. The modular electrical-cabinet mounting apparatus as claimed in claim 2, wherein the frame has a width which matches or substantially matches a width of the base wall assembly.

4. The modular electrical-cabinet mounting apparatus as claimed in claim 2, wherein the panel comprises at least one cabinet locator.

5. (canceled)

6. The modular electrical-cabinet mounting apparatus as claimed in claim 1, wherein each cabinet support member comprises a cabinet plinth through which the cabling access aperture passes.

7. The modular electrical-cabinet mounting apparatus as claimed in claim 6, wherein the cabinet plinth is sub-divided into a plurality of plinth sections, each plinth section having an openable access door thereto.

8. The modular electrical-cabinet mounting apparatus as claimed in claim 1, wherein a plurality of different cabinet-support members is provided, each of the different cabinet-support members having a cabling access aperture of a different dimension.

9. The modular electrical-cabinet mounting apparatus as claimed in claim 1, wherein at least one platform member is provided as a cover panel.

10. The modular electrical-cabinet mounting apparatus as claimed in claim 9, wherein the cover panel is dimensioned so as to have a width greater than a width of a cabinet door of an electrical cabinet suitable for engaging with the multi-part support platform.

11. The modular electrical-cabinet mounting apparatus as claimed in claim 7, wherein a plurality of cabinet-support members is provided, a said cover panel being positioned between each consecutive pair of cabinet-support members to form the multi-part support platform.

12. The modular electrical-cabinet mounting apparatus as claimed in claim 7, wherein the cover panel is openable to permit user access to the cabling void.

13. The modular electrical-cabinet mounting apparatus as claimed in claim 1, wherein each of the platform members includes a seating element engagable with an inner perimeter of the base wall assembly.

14. (canceled)

15. The modular electrical-cabinet mounting apparatus as claimed in claim 1, wherein the base wall assembly is formed from a plurality of discrete wall sections which are interconnectable to form different dimensional variants.

16. The modular electrical-cabinet mounting apparatus as claimed in claim 1, further comprising a cabling duct engagable with the base wall assembly for providing lateral access to the cabling void.

17. The modular electrical-cabinet mounting apparatus as claimed in claim 16, wherein at least one platform member is provided as a cover panel, and wherein the cabling duct is aligned or substantially aligned to a center of the cover panel when the multi-part support platform is assembled.

18. (canceled)

19. The modular electrical-cabinet mounting apparatus as claimed in claim 1, in the form of a kit of parts.

20. A modular electrical-cabinet system comprising: a modular electrical-cabinet mounting apparatus as claimed in claim 1, and an electrical cabinet associated with each of the cabinet-support members, the or each cabinet being dimensioned to engage with and cover the corresponding cabling access aperture.

21. The modular electrical-cabinet system as claimed in claim 20, wherein a door of each electrical cabinet opens towards or away from a subsequent electrical cabinet.

22. The modular electrical-cabinet system as claimed in claim 20, wherein each electrical cabinet is a rail controller-unit cabinet.

23. A method of providing a plurality of sequential electrical cabinets in a spaced apart relationship at a site requiring electrical cabling access, the method comprising the steps of:
a] constructing a base wall assembly defining a cabling void, the base wall assembly having a length;
b] interconnecting a plurality of individual platform members together to form a multi-part support platform which has a length greater than or equal to the length of the base wall assembly, wherein at least two said platform members are cabinet-support members having a cabling access aperture therethrough, the support platform selectively assembled so that the cabinet-support members are in a spaced-apart relationship along the length of the support platform;
c] mounting the support platform to the base wall assembly; and
d] mounting electrical cabinets onto the cabinet-support members.

24. (canceled)

25. (canceled)
